(19) United States
(12) Patent Application Publication
(10) Pub. No.: US 2002/0110341 A1
(43) Pub. Date: Aug. 15, 2002

(54) Manufacturing method for edge-emitting or edge-coupled waveguide optoelectronic devices

(76) Inventor: Rong-Heng Yuang, Hsinchu (TW)

Correspondence Address: BIRCH STEWART KOLASCH & BIRCH, PO BOX 747, FALLS CHURCH, VA, 22040-0747, US

(21) Appl. No.: 09/880,852

(22) Filed: Jun. 15, 2001

(30) Foreign Application Priority Data
Feb. 9, 2001 (TW) 90102840

(51) Int. Cl. G02B 6/136

(52) U.S. Cl. 385/129; 257/13

(57) ABSTRACT

A manufacturing method for edge-emitting or edge-coupled waveguide optoelectronic devices (such as edge-emitting waveguide laser diodes or edge-coupled waveguide photodiodes). The method uses a high density plasma (HDP) reactive ion etching (RIE) technique to etch the semiconductor layer of an optoelectronic device at wafer level to form facets for light to go in or out. One can then coat the facets before chipping a wafer, thus avoiding the trouble of cleaving the wafer into bars as in the prior art. This method can increase the efficiency and reliability of devices and lower the manufacturing cost.

### BACKGROUND OF THE INVENTION

1. Field of Invention

The present invention relates to a manufacturing method of waveguide optoelectronic device and, more particularly, to a manufacturing method for edge-emitting or edge-coupled waveguide optoelectronic device, such as edge-emitting laser diodes and edge-coupled photodiodes.

2. Related Art

A conventional edge-emitting waveguide optoelectronic device, such as the edge-emitting ridge waveguide laser diode depicted in FIGS. 1A and 1B, includes a semiconductor substrate 2 (such as an n+substrate) and a lower cladding and guiding layer 3, an active layer 4, an upper cladding and guiding layer 5, and a cap layer 6 formed in order on the top surface of the semiconductor substrate 2 using the epitaxial crystal growth technique. The cap layer 6 and the upper cladding and guiding layer 5 are properly etched into a ridge shape. The cap layer 6 and the upper cladding and guiding layer 5 are formed in order a dielectric layer 7 and a metal layer 8 (such as a p-type metal electrode) with a proper contact window. The back surface of the semiconductor substrate 3 is formed with another metal layer 9 (such as an n-type metal electrode). Light 1 emitted from the laser diode can shoot out from a pair of facets 10 (or one of them) formed on both sides of the laser diode. The facets 10 have facet coatings 11 to protect the device and to increase the light-emitting efficiency. One can also apply an anti-reflecting coating on one facet and a high reflection coating on the other. Most of the light will then shoot out from one facet only.

A conventional edge-coupled waveguide optoelectronic device, such as the edge-coupled waveguide PIN photodiode shown in FIGS. 2A and 2B, includes a semiconductor substrate 12 (such as an n+substrate) and a buffer layer 13, an absorption layer 14, and a window layer 15 formed in order on the top surface of the semiconductor 12. The window layer 15 is formed with a p+area 16 and a dielectric layer 17 with a proper contact window. The p+area 16 is formed with a p-type metal electrode 18. The back surface of the semiconductor substrate 12 is formed with an n-type metal electrode 19. Light 21 can come in from a facet 20 formed on one side of the photodiode. The facet 20 has an anti-reflecting coating 22 to increase the efficiency of entering light.

Conventionally, one has to cut a wafer into bar chips in order to obtain facets before coating on the facets on the edges of the edge-emitting laser diode or the edge-coupled photodiode. The bar chips are aligned in parallel in an e-beam evaporator for performing anti-reflecting layer coating, high-reflection layer coating, or other passivation coatings. The drawback of this method is that the facets are exposed to the environment for a longer time and are susceptible to oxidation problems, lowering the reliability of devices. Furthermore, the facet coating procedure is tedious. During the procedure of cleaving the wafer, crystal is likely broken into pieces, thus lowering the yield and increasing the cost. Moreover, it is often unable to accurately define the relative positions of the facets on the optoelectronic devices when cleaving the wafer. This greatly affects the precision of optical paths in the devices so that an optimal result is unlikely to be obtained.

In view of the foregoing, it is then necessary to provide a new manufacturing method for edge-emitting or edge-coupled waveguide optoelectronic devices that can solve the above-mentioned problems.

### SUMMARY OF THE INVENTION

An objective of the invention is to provide a manufacturing method for edge-emitting or edge-coupled optoelectronic devices that has simple processes, high precision, and is suitable for mass production.

Pursuant to the above objective, the invention uses a high density plasma (HDP) reactive ion etching (RIE) technique in place of the wafer cleaving technique used in the prior art to form facets for light to go in or out. The disclosed method uses the RIE technique to etch the semiconductor layer that constitutes optoelectronic devices before chipping the wafer so as to obtain proper facets for light to go in or out. The semiconductor layer constituting the optoelectronic devices is formed on the wafer by the conventional epitaxial crystal growth technique. The whole wafer is coated through a batch process before chipping the wafer. For example, a plasma enhanced chemical vapor deposition (PECVD) method can be employed to form a coating on the facets without cleaving the wafer. The current method can simplify the manufacturing processes and is particularly useful for mass-producing edge-emitting or edge-coupled optoelectronic devices, thus lowering the cost.

In accordance with the disclosed method, relative positions of the facets can be precisely defined by photolithography before the facets are formed by the RIE technique. Therefore, one can have an accurate handle on optical paths in the optoelectronic devices. For example, a smaller cavity length can be formed in a laser diode, or the distance from an incident edge to an active area can be accurately controlled in a photodiode. Thus, an optoelectronic device can reach an optimal design, greatly enhancing the quality and reliability of the device.

Other features and advantages of the present invention will be apparent from the following detailed description, which proceeds with reference to the accompanying drawings. The drawings are not necessarily to scale.

### BRIEF DESCRIPTION OF THE DRAWINGS

The present invention will become more fully understood from the detailed description given hereinbelow illustration only, and thus are not limitative of the present invention, and wherein:

FIG. 1 A is a three-dimensional diagram of an edge-emitting ridge waveguide laser diode in the prior art;

FIG. 1B is a longitudinal cross-sectional view of the edge-emitting ridge waveguide laser diode in FIG. 1A;

FIG. 2A is a three-dimensional diagram of an edge-coupled waveguide PIN photodiode in the prior art;

FIG. 2B is a longitudinal cross-sectional view of the edge-coupled waveguide PIN photodiode in FIG. 2A;

FIGS. 3A and 3B depict the structure of an edge-emitting ridge waveguide laser diode of the invention;

FIGS. 4A through 4R show the cross-sectional views of steps in the manufacturing method for an edge-emitting ridge waveguide laser diode according to the invention;

FIG. 5 shows the structure of an edge-coupled waveguide PIN photodiode of the invention; and

FIGS. 6A through 6M show the cross-sectional views of steps in the manufacturing method for an edge-coupled waveguide PIN photodiode according to the invention.

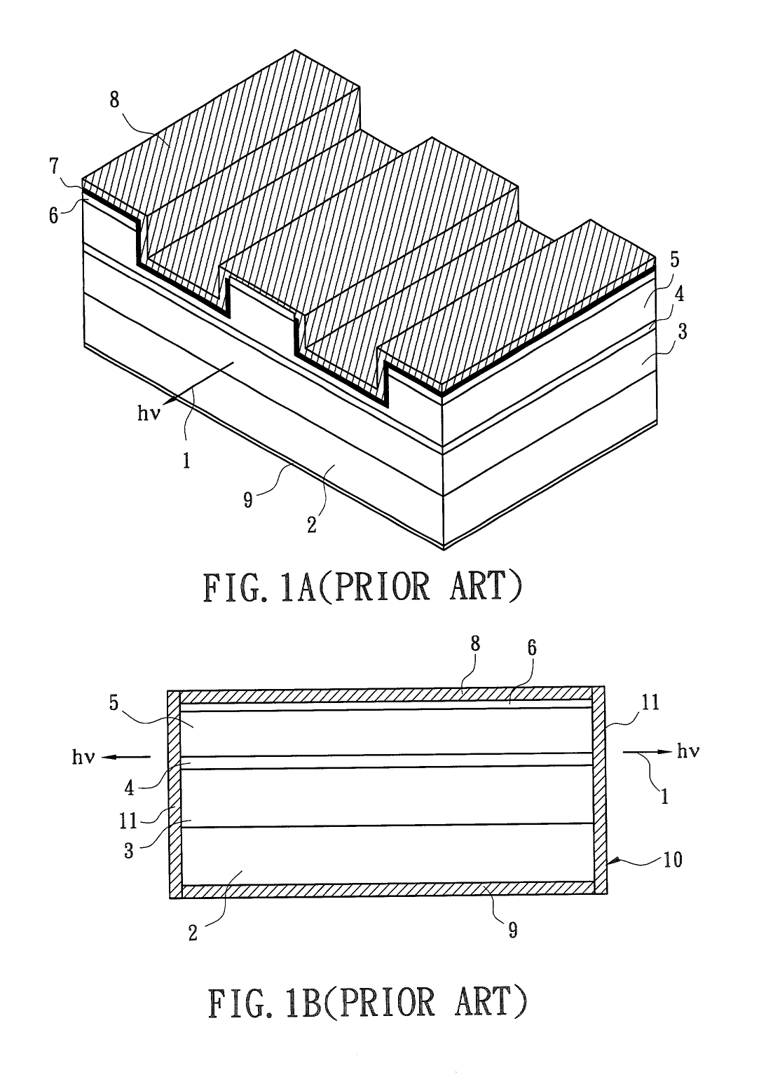

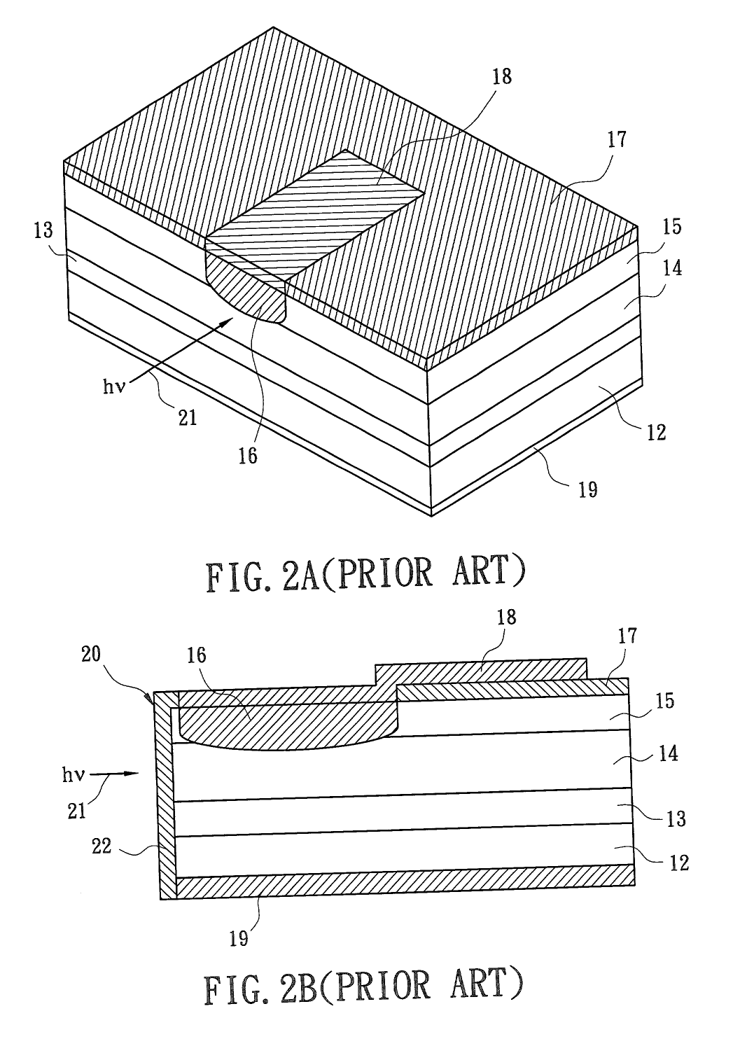

### DETAILED DESCRIPTION OF THE INVENTION

The present invention will be apparent from the following detailed description, which proceeds with reference to the accompanying drawings, wherein the same references relate to the same elements.

First Embodiment

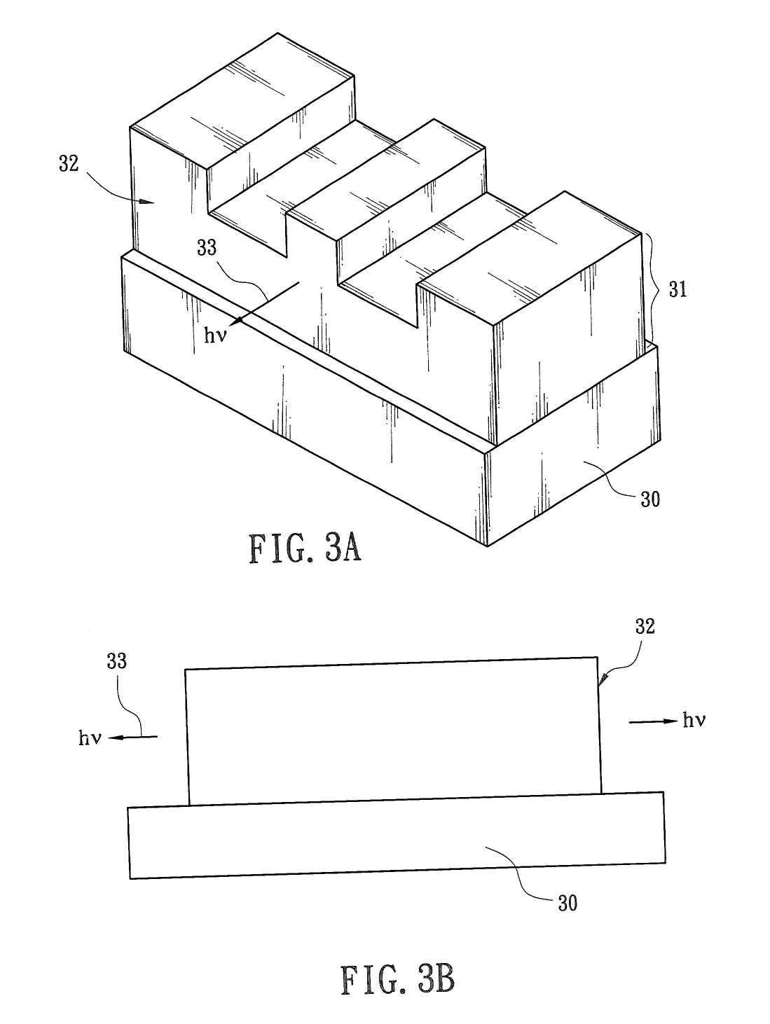

With reference to FIGS. 3A and 3B, a reactive ion etching (RIE) technique is employed at the wafer level to etch an epitaxial semiconductor layer 31 on a semiconductor substrate 30 (such as an n+wafer). Therefore, a pair of parallel facets 32 can be obtained without the need to perform wafer cleaving. The facet pair 32 allows light emitted from the laser diode to go out. The distance between the facet pair 32 is the so-called cavity length, e.g.,300 μm in this embodiment. The outgoing direction of the light 33, the cavity direction (hereinafter as the longitudinal direction), is perpendicular to the facets 32. The direction perpendicular to the cavity direction is called the transverse direction hereinafter.

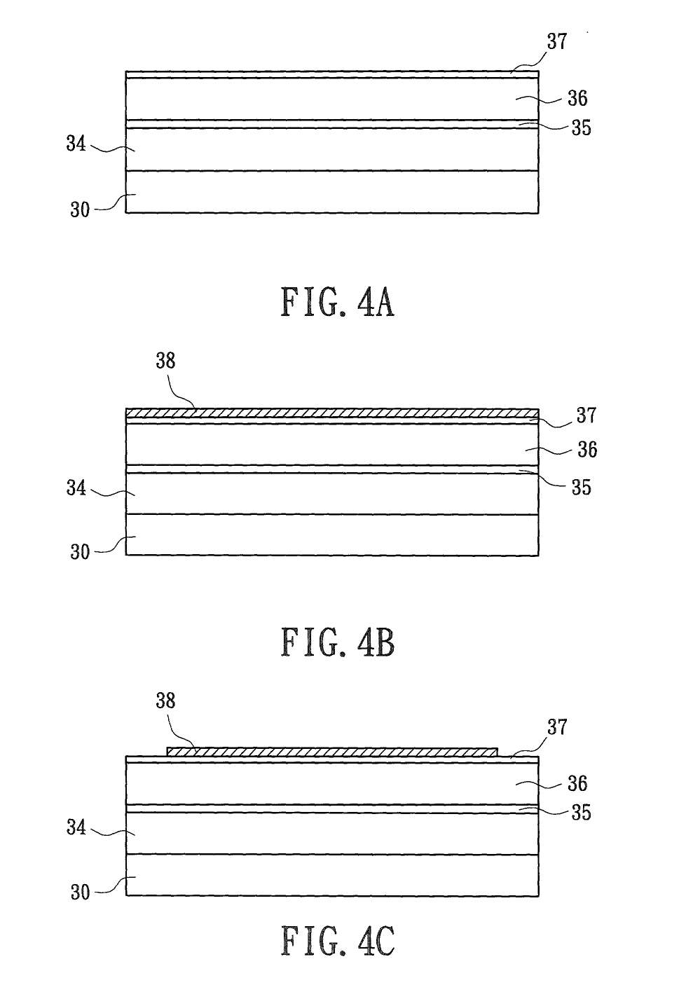

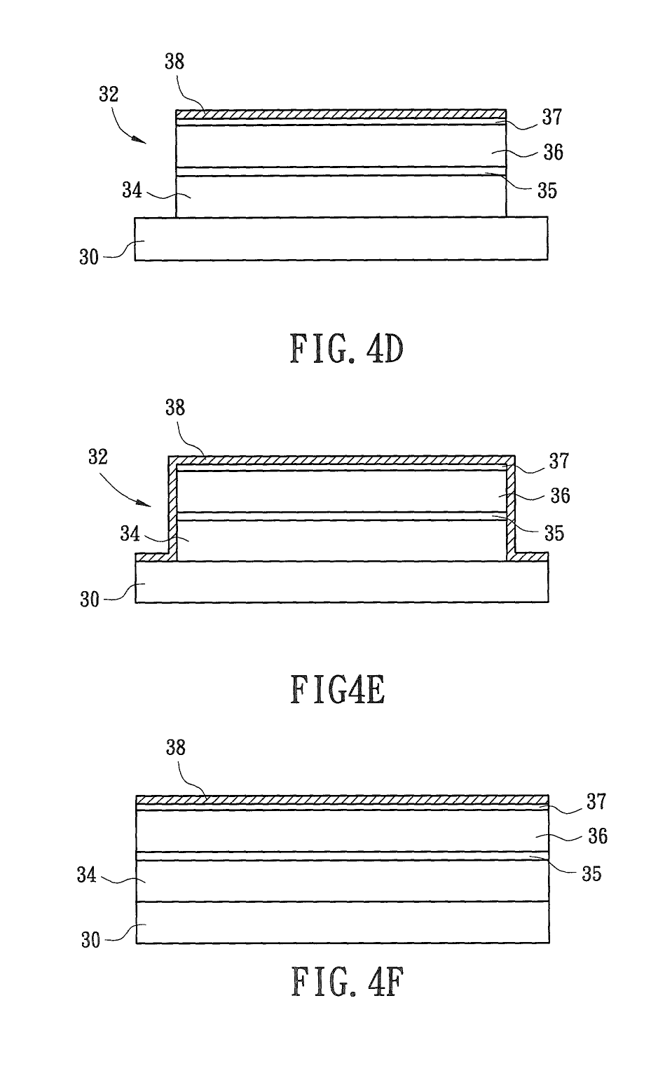

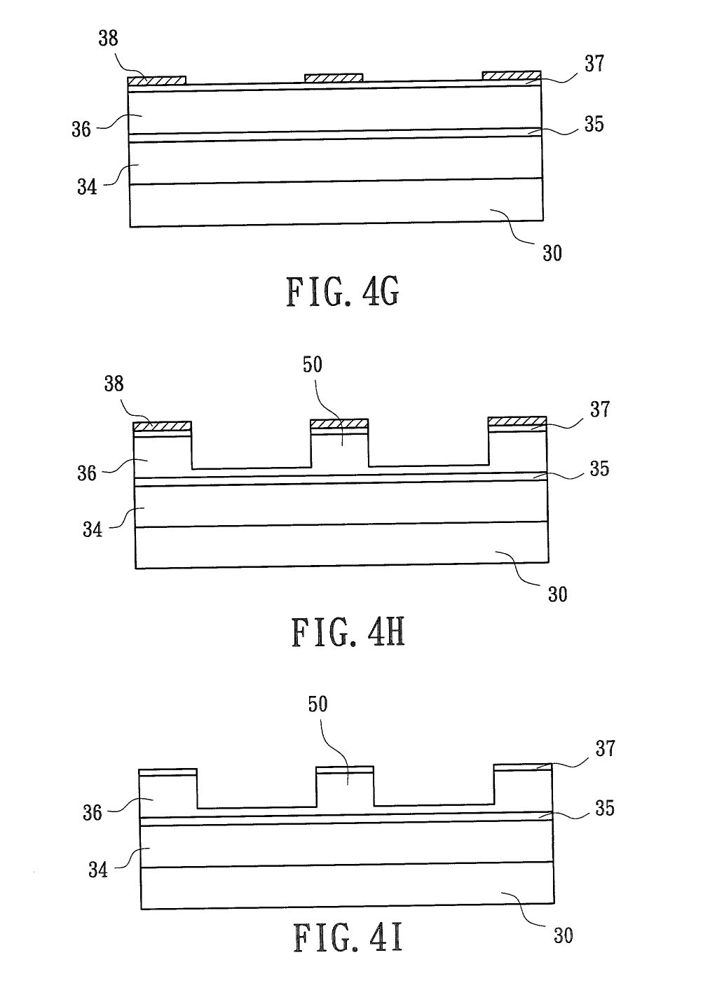

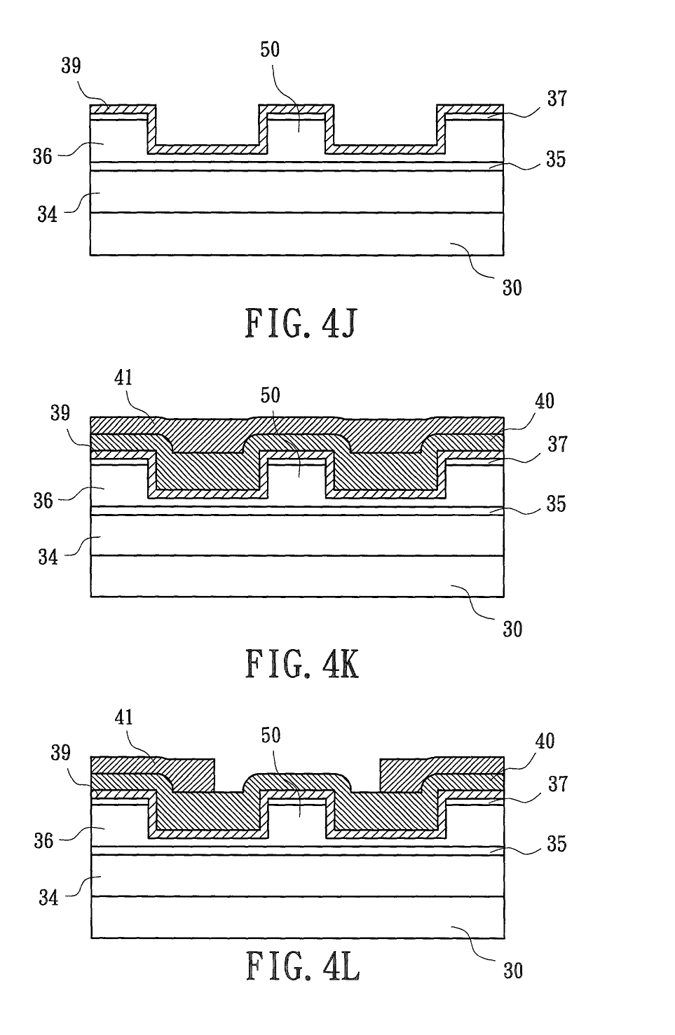

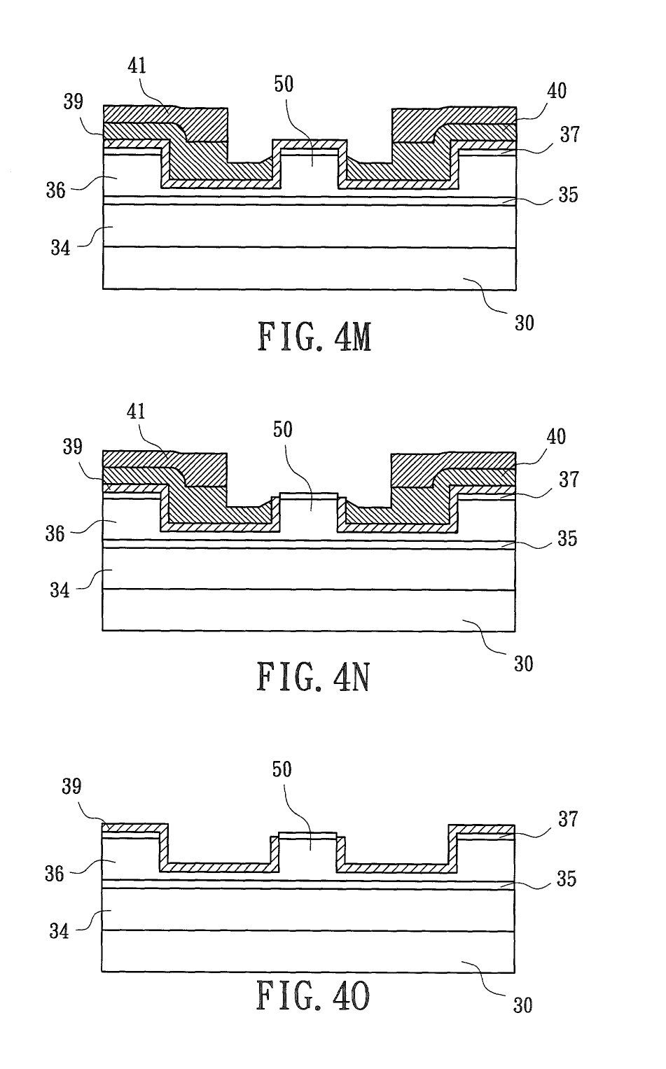

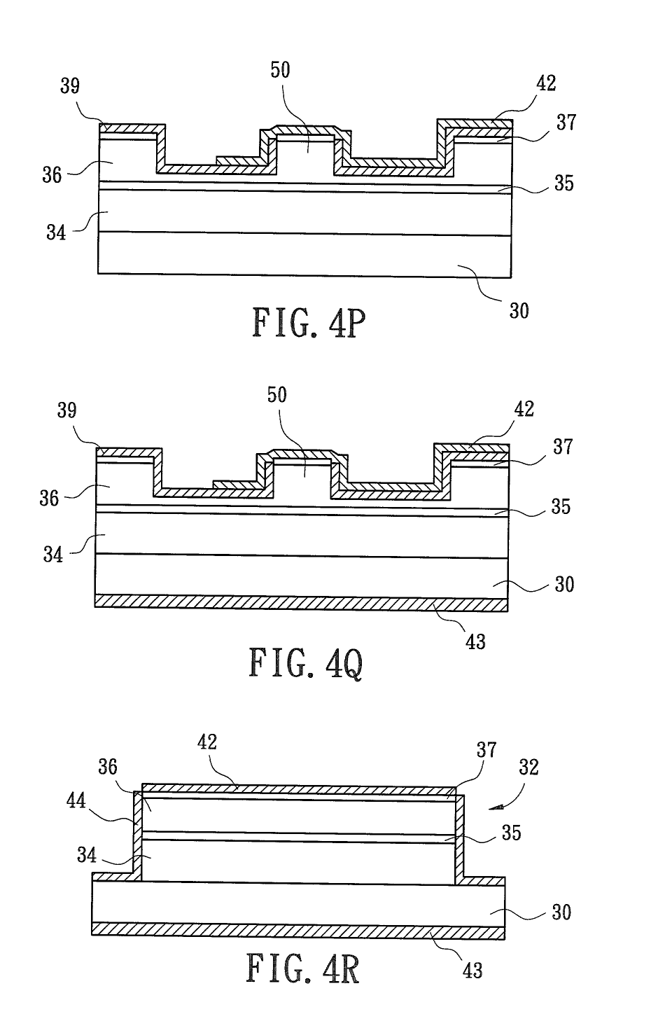

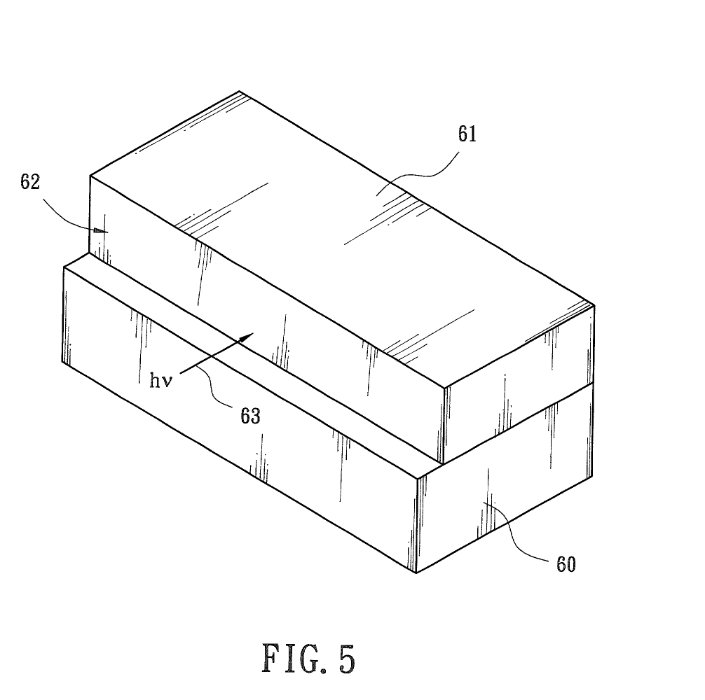

With reference to FIG. 4A, a semiconductor substrate 30 is formed with a semiconductor layer structure that a laser diode needs. Such a semiconductor layer structure contains, for example, a lower cladding and guiding layer 34, an active layer 35, an upper cladding and guiding layer 36 and a cap layer 37. The semiconductor substrate 30 can be an n+wafer. The lower cladding and guiding layer 34, the active layer 35, the upper cladding and guiding layer 36 and the cap layer 37 can be grown from bottom to top on the wafer using the conventional epitaxial crystal growth technique.

As shown in FIG. 4B, a dielectric layer 38 is formed on the cap layer 37. The dielectric layer 38 can be formed using the plasma enhanced chemical vapor deposition (PECVD) method. With reference to FIG. 4C, the dielectric layer 38 is patternized using photolithography and etching techniques (such as the RIE) to accurately define the relative positions of facets on a laser diode. As shown in FIG. 4D, the RIE is used to etch and remove the exposed cap layer 37, the upper cladding and guiding layer 36, the active layer 35, and the lower cladding and guiding layer 34, forming a pair of parallel facets 32 along the edge of the cap layer 37, the upper cladding and guiding layer 36, the active layer 35, and the lower cladding and guiding layer 34.

Afterwards, as shown in FIG. 4E, the dielectric layer 38 can be formed on the exposed surface of the facets 32 and the semiconductor substrate 30 using the PECVD method. FIG. 4F is a horizontal cross section of the configuration shown in FIG. 4E. With reference to FIG. 4G, the dielectric layer 38 on the cap layer 37 is removed using the RIE method so as to define a ridge structure pattern. As shown in FIG. 4H, the exposed cap layer 37 and the exposed upper cladding and guiding layer 36 are removed using the RIE method. The cap layer 37 and the upper cladding and guiding layer 36 are formed with a ridge structure 50.

With reference to FIG. 41, the remaining dielectric layer 38 can be removed using the wet etching method. As shown in FIG. 4J, the exposed semiconductor layer is grown with a passivation layer 39. As shown in FIG. 4K, a first photoresist layer 40 and a second photoresist layer 41 are formed in order on the passivation layer 39. Both the first photoresist layer 40 and the second photoresist layer 41 can be formed by spin coating. Utilizing the fact that the two layers of photoresist have different sensitivities to light of different wavelengths, the second photoresist layer (the upper one) only interact with light of wavelengths in a specific range while the first photoresist layer (the lower one) does not have any reaction in this wavelength range at all. Therefore, the first photoresist layer 40 can be a deep UV photoresist, which only interacts with light with a wavelength smaller than 300 nm. The second photoresist 41 can be a G-line and I-line photoresist, which interacts with light with a wavelength larger than 300 nm.

Afterwards, as shown in FIG. 4L, a window corresponding to the ridge structure 50 is opened on the second photoresist layer 41 using exposure and development techniques. This is achieved by shining light on the second photoresist using a G-line mask aligner. At the moment, light only interacts with the second photoresist. The first photoresist does not have any reaction. This method opens a window on the second photoresist while leaving the first photoresist exposed to the environment. With reference to FIG. 4M, the first photoresist layer 40 is then etched using the RIE method until the passivation layer 39 on top of the ridge structure 50 is exposed. As shown in FIG. 4N, the passivation layer 39 on top of the ridge structure 50 is etched and removed, leaving a contact window on the top of the ridge structure 50.

Afterwards, as shown in FIG. 40, the first photoresist layer 40 and the second photoresist layer 41 are removed. With reference to FIG. 4P, a metal layer 42 (such as a p-type electrode layer) is formed on the ridge structure 50 and the passivation layer 39. As shown in FIG. 4Q, another metal layer 43 (such as an n-type electrode layer) is formed on the back surface of the semiconductor substrate 30. Before forming the metal layer 43, the semiconductor substrate 30 can be machined thinner. FIG. 4R shows a longitudinal cross section on the configuration show in FIG. 4Q. The facets 32 are coated with an anti-reflecting layer 44 in a proper way (such as the PECVD method) before the wafer cleaving during the wafer level. This avoids the trouble of chipping the wafer into bars that occurs in the prior art.

Second Embodiment

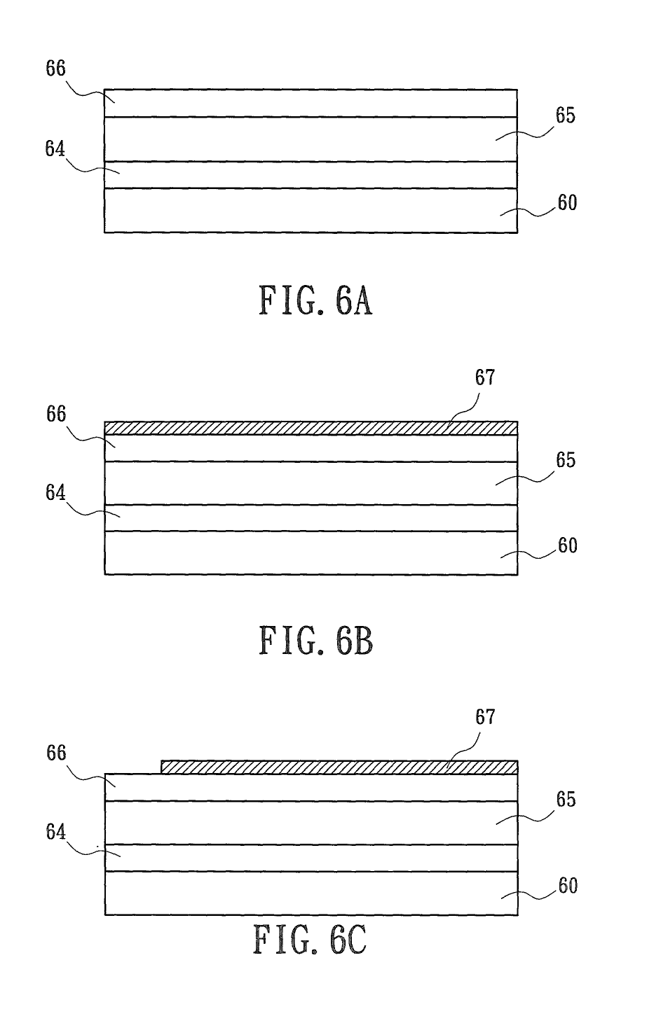

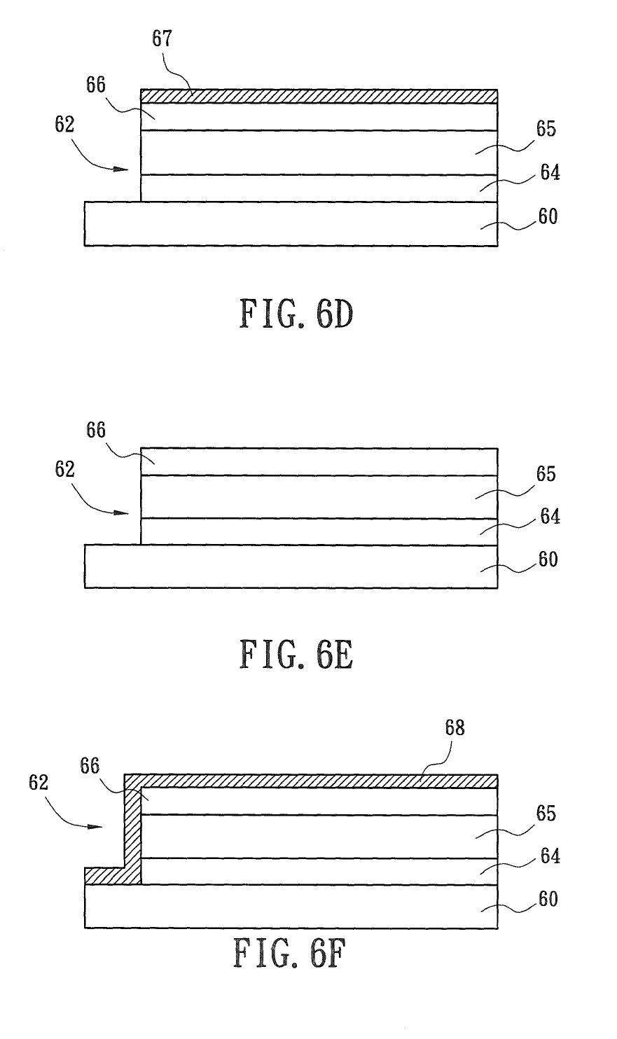

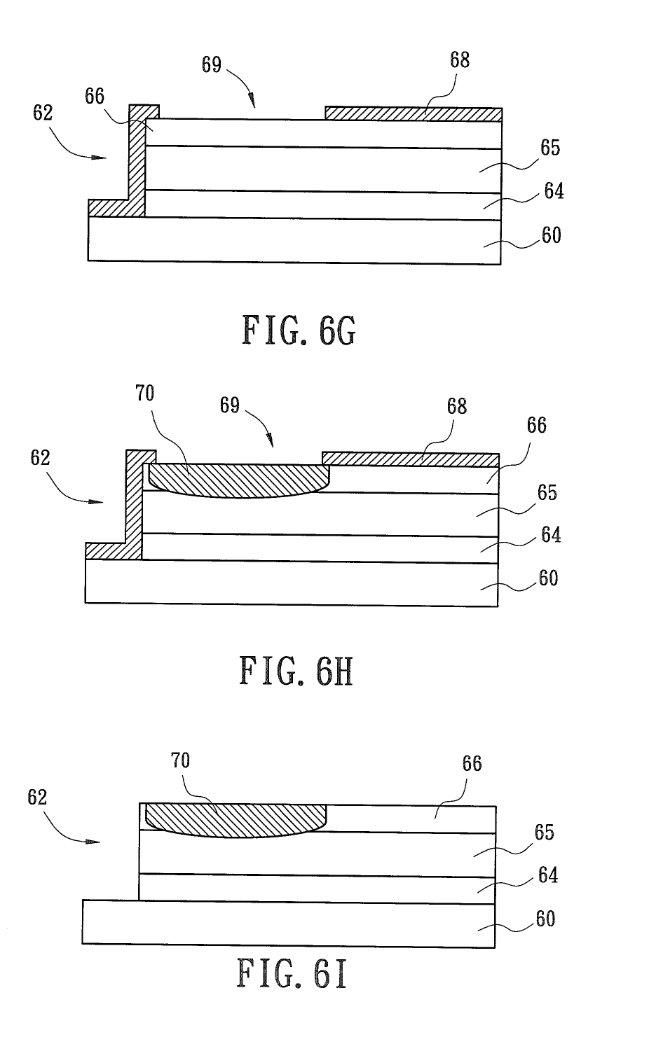

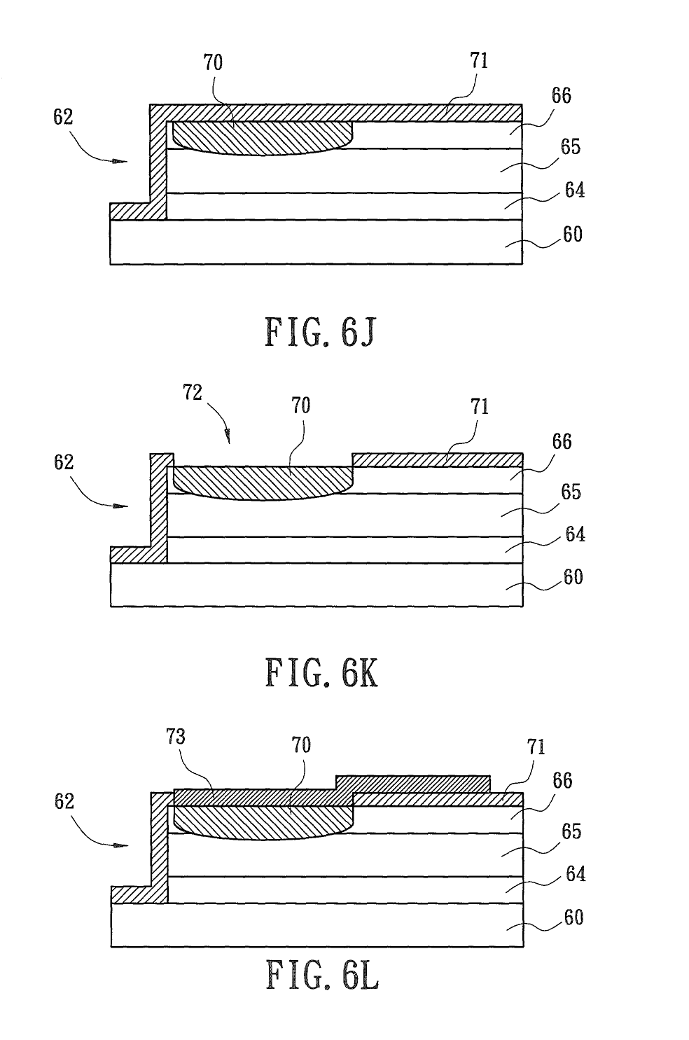

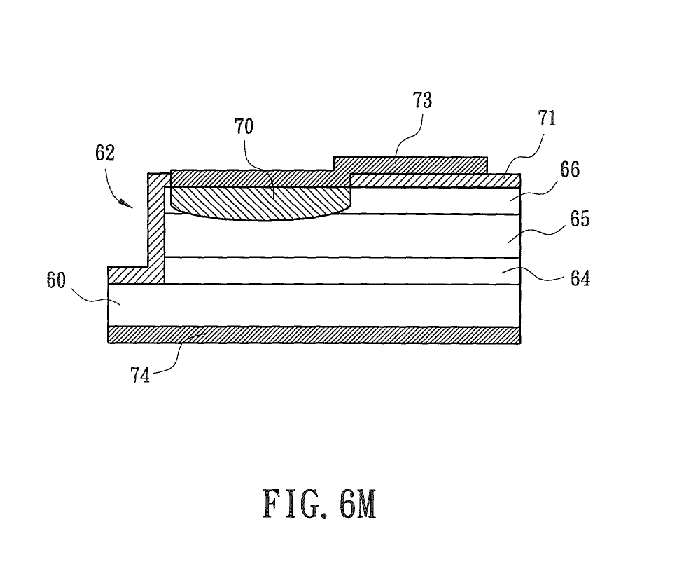

With reference to FIG. 5 for an edge-coupled photodiode of the invention, a semiconductor layer 61 on a semiconductor substrate 60 (such as an n+wafer) is etched using the RIE. Therefore, an incident facet 62 for light 63 to enter is formed on one side of the semiconductor layer 61 without the need for wafer cleaving. The incident direction of light 63 (the longitudinal direction) is roughly perpendicular to the facet 62. With reference to FIG. 6A, a semiconductor layer structure for constituting a photodiode is formed on the semiconductor 60, including a buffer layer 64, an absorption layer 65 and a window layer 66. The semiconductor substrate 60 can be an n+wafer. As shown in FIG. 6B, the window layer 66 is formed with a first dielectric layer 67. For example, the first dielectric layer 67 can be formed by the PECVD method. With reference to FIG. 6C, the first dielectric layer 67 is patternized using photolithography and etching techniques (such as the RIE) to accurately define the relative positions of facets on the photodiode. As shown in FIG. 6D, the RIE is used to etch and remove the exposed window layer 66, the exposed absorption layer 65, and the exposed buffer layer 64, forming a facet 62 for light to enter along one side of the window layer 66, the absorption layer 65 and the buffer layer 64.

Afterwards, as shown in FIG. 6E, the first dielectric layer 67 can be removed by wet etching. As shown in FIG. 6F, the exposed surfaces of the window layer 66, the facet 62 and the semiconductor substrate 60 can be formed with a second dielectric layer 68 using the PECVD method too. With reference to FIG. 6G, the second dielectric layer 68 is etched using the RIE method so as to open a proper window 69. As shown in FIG. 6H, the second dielectric layer 68 is used as a diffusive mask to impurity diffusion, such as the Zn diffusion, forming a p+area 70 on the window layer 66 at the window 69. As shown in FIG. 61, the second dielectric layer 68 is removed by wet etching.

As shown in FIG. 6J, a third dielectric layer is formed on the exposed surfaces of the window layer 66, the facet 62, and the semiconductor substrate 60. The third dielectric layer 70 can simultaneously be an anti-reflecting coating to increase the incident light efficiency. As shown in FIG. 6K, the third dielectric layer 71 is etched using the RIE technique to open a contact window 72 corresponding to the p+area 70. As shown in FIG. 6L, a proper metal p-type electrode 73 is formed on the contact window 72 and the third dielectric layer 71. As shown in FIG. 6M, a metal n-type electrode 74 is formed on the back surface of the semiconductor substrate 60. Of course, the semiconductor substrate 60 can be machined thinner before forming the metal n-type electrode 74.

Through the above-mentioned steps, an optimized edge-coupled waveguide PIN photodiode can be obtained. Furthermore, the facet of the photodiode is formed with an anti-reflecting coating at the wafer level so that the manufacturing procedure is more suitable for batch process mass production.

Although the invention has been described with reference to specific embodiments, this description is not meant to be construed in a limiting sense. Various modifications of the disclosed embodiments, as well as alternative embodiments, will be apparent to persons skilled in the art. It is, therefore, contemplated that the appended claims will cover all modifications that fall within the true scope of the invention.

What is claimed is:

1. A manufacturing method for edge-emitting/edge-coupled waveguide optoelectronic devices with at least one facet for light to escape or enter, which is characterized in that the at least one facet is obtained by etching a semiconductor layer of the optoelectronic device at the wafer level.

2. The method of claim 1, wherein the etching method for obtaining the facet is the reactive ion etching (RIE) method.

3. The method of claim 1 comprising a step of defining the at least one facet position using the photolithography.

4. The method of claim 1, wherein the at least one of the facet is coated with a passivation coating.

5. The method of claim 4, wherein the passivation coating is an anti-reflecting coating.

6. The method of claim 4, wherein the passivation coating is formed by the plasma enhanced chemical vapor deposition (PECVD).

7. The method of claim 1, wherein the optoelectronic device is a laser diode (LD).

8. The method of claim 7, wherein the LD is a ridge waveguide LD.

9. The method of claim 7, wherein the at least one facet includes a pair of parallel facets.

10. The method of claim 7, wherein the etched semiconductor layer includes a cap layer, an upper cladding and guiding layer, an active layer, and a lower cladding and guiding layer.

11. The method of claim 1, wherein the optoelectronic device is a photodiode (PD).

12. The method of claim 11, wherein the PD is a PIN photodiode.

13. The method of claim 11, wherein the etched semiconductor layer includes a window layer, an absorption layer, and a buffer layer.

14. A structure of an edge-emitting/edge-coupled waveguide optoelectronic device with at least one facet for light to escape or enter, which is characterized in that the at least one facet is formed on one side of the optoelectronic device by etching a semiconductor layer of the optoelectronic device.

15. The structure of claim 14, wherein the at least one facet is formed by the RIE method.

16. The structure of claim 14, wherein the at least one facet is coated with an antireflecting coating.

17. The structure of claim 16, wherein the anti-reflecting coating is formed by the PECVD method.

18. The structure of claim 14, wherein the optoelectronic device is an LD.

19. The structure of claim 18, wherein the LD is a ridge waveguide LD.

20. The structure of claim 18, wherein the at least one facet includes a pair of parallel facets.

21. The structure of claim 14, wherein the optoelectronic device is a PD.

22. The structure of claim 21, wherein the PD is a PIN photodiode.
